(19) United States
(12) Patent Application Publication
(10) Pub. No.: US 2020/0213430 A1
(43) Pub. Date: Jul. 2, 2020

(54) Wire drawing device for metal mobile phone back case

(71) Applicant: Jian'er Chai, Tianjin City (CN)

(72) Inventor: Jian'er Chai, Tianjin City (CN)

(21) Appl. No.: 16/814,958

(22) Filed: Mar. 10, 2020

(30) Foreign Application Priority Data
Nov. 18, 2019 (CN) 2019111301575

(51) Int. Cl. H04M 1/02; H05K 5/02; H05K 5/04; H05K 7/14

(52) U.S. Cl. CPC H04M 1/026; H05K 7/14; H05K 5/04; H05K 5/0247

(57) ABSTRACT

The invention discloses a wire drawing device for a rear case of a metal mobile phone, which includes a fuselage, and all of the support rods are symmetrically mounted on both sides of the fixing block. The fixing block is provided with a first spring space and the motor base moves to a third position The left side of the space is stuck and positioned. The left and right movement of the frosted stone is controlled by the threaded screw. The frosted stone contacts the mobile phone case to move left and right. Good control of cleaning time and cutting time of plastic film, the call spring controls the pressure block to slide up and down flexibly, which can make the plastic film fit without damaging the surface of the drawn mobile phone case.

### CROSS-REFERENCE TO RELATED APPLICATIONS

The present application claims priority from Chinese application No. 2019111301575 filed on Nov. 18, 2019 which is hereby incorporated by reference in its entirety.

### FIELD OF TECHNOLOGY

The invention relates to the field of metal material, and in particular relates to a wire drawing device for metal mobile phone back case.

### TECHNICAL FIELD

Metal wire drawing is the manufacturing process of repeatedly scraping aluminum plates out of sand with sandpaper. During the wire drawing process, the special coating technology after anodizing can make the metal surface form a coating layer containing the metal component, clearly showing each subtle Silk marks, which give a fine hair shine to the metallic matte. In recent years, more and more products' metal shells have used metal wire drawing technology to play a beautiful and anti-erosion role, while manual wire drawing is time-consuming and labor-intensive, and the quality is not guaranteed. Therefore, the invention needs to be solved to solve the above problems.

### CONTENT OF THE INVENTION

An object of the present invention is to provide a wire drawing device for a rear shell of a metal mobile phone, which is used to overcome the above defects in the prior art.

A wire drawing device for a back cover of a metal mobile phone according to an embodiment of the present invention includes a fuselage. A wire drawing space is provided in the fuselage, and a fixing member for fixing the mobile phone case is provided in the wire drawing space. The fixing member includes A support rod installed in the drawing space is rotatably mounted on all sides of the support rod, and a fixing block is symmetrically arranged on both sides of the support rod. A first spring space is provided in the fixing block, and an outer side wall of the first spring space and the support rod are installed. A first spring is fixedly installed between the outer sides, and the mobile phone casing is sleeved on the support rod, and the first spring drives the support rod to fix the mobile phone casing on the support rod.

The drawing space is provided with a drawing member for drawing the surface of the mobile phone case, and the drawing member includes a thread block slidingly installed on the upper side of the support rod in the drawing space, and a matte is fixedly installed on the lower side of the thread block. Block base, a matte block is fixedly installed on the lower side of the matte block base, and the matte block can be contacted with the mobile phone case for drawing.

A fan blade space communicating with the brushed space is located on the right side of the frosted block in the rear wall of the brushed space, and the fan blade space is provided with a metal scrap for cleaning the metal scraps remaining on the mobile phone case after the brushing. A cleaning component, which includes a fan blade rotatingly installed in the fan blade space, and when the brushed mobile phone case moves to the front side of the fan blade, the fan blade can be rotated to blow away and remain in the fan blade. Metal shavings on the phone case.

On the basis of the above technical solution, the fixing member further includes a sliding space provided on the lower side of the drawing space and communicating with the drawing space, a motor base is slidably installed in the sliding space, and a motor base is fixedly installed in the motor base. A motor, a fixed shaft is fixed on the output shaft of the first motor, the fixed shaft is fixedly connected to the support rod, a second spring space is provided in the left wall of the sliding space, and the left wall of the second spring space A first current-carrying magnet is fixedly installed therein, and a slide bar is slidably installed in the second spring space. A first permanent magnet is fixedly installed in a left side surface of the slide bar, and a left-side surface of the first permanent magnet is connected to the first current A second spring is fixedly installed between the right sides of the magnet.

Based on the above technical solution, a third spring space is provided in the first positioning space, a second positioning space, and a third positioning space, and a second energizing magnet is fixedly installed in the rear wall of the third spring space. A fixed rod is slidably installed in the two energized magnets. A second permanent magnet is fixedly installed in the rear side of the fixed rod. A third spring is fixedly installed between the rear side of the second permanent magnet and the front side of the second energized magnet.

Based on the above technical solution, the wire drawing component further includes a second motor fixedly installed in the left wall of the wire drawing space, and a threaded screw is fixedly installed on the output shaft of the second motor. The threaded screw and the threaded block Threaded connection.

On the basis of the above technical solution, the cleaning component further includes a first gear space provided on a lower side of the fan space and communicating with the drawing space, and an upper side of the first gear space is located behind the fan space. A first helical gear space is provided on the side, and a second rotation shaft is rotatably installed between the top wall of the first gear space and the bottom wall of the first helical gear space, and the lower side of the second rotation shaft is located on the first gear. A second gear is fixedly installed in the space, and a first helical gear is fixedly installed in the first helical gear space on the upper side of the second rotation shaft. The front wall of the first helical gear space and the rear wall of the fan space are fixed. The fan blade shaft is installed between the first and second helical gears, and the second helical gear is fixedly installed in the first helical gear space. The second helical gear is in mesh with the first helical gear. The fan blades are fixedly connected, a first gear is fixedly mounted on the fixed shaft, and the first gear can mesh with the second gear.

On the basis of the above technical solution, a thin film space with an opening downward is located on the right side of the fan space in the top wall of the drawing space, and a support shaft is rotatably installed in the film space, and the film shaft is fixedly installed on the support shaft. A plastic film is wound on the film shaft, a fourth spring space is located on the right side of the film space in the top wall of the drawing space, and a pressure block is slidably installed in the fourth spring space, and the upper side of the pressure block A fourth spring is fixedly mounted to the top wall of the fourth spring space, and a third gear space is provided on the right side of the fourth spring space of Sosohu in the top wall of the drawing space, and the top wall of the drawing space is located in the A second helical gear space is provided on the right side of the third gear space, and a second gear space is provided on the lower side of the second helical gear space in the rear wall of the drawing space. A third rotation shaft is rotatably installed between the bottom walls of the two helical gear spaces, and a third gear is fixedly installed in the second gear space under the third rotation shaft, and the third gear can mesh with the first gear, Said the A third helical gear is fixedly installed on the rotation shaft in the second helical gear space, and a fourth rotation shaft is rotatably installed between the right wall of the third gear space and the left wall of the second helical gear space. A right side of the rotation shaft is fixedly installed in the second helical gear space, and a fourth helical gear is fixedly engaged with the third helical gear. The left side of the fourth rotation shaft is located in the third gear space. A fourth gear is fixedly installed therein, and a rack space is provided between the drawing space in the third gear space and the water space. A rack is slidably installed in the rack space, and the rack meshes with the fourth gear. A cutter bar is fixedly installed on the lower side of the rack.

The beneficial effects of the present invention are: the present invention uses a threaded screw to control the left and right movement of the frosted stone, and the frosted stone contacts the mobile phone case to move left and right to perform drawing. It can better control the cleaning time and the cutting time of the plastic film. The call spring controls the pressure block to slide up and down flexibly, which can make the plastic film fit without damaging the surface of the drawn mobile phone case, which is worth promoting.

### BRIEF DESCRIPTION OF THE DRAWINGS

In order to more clearly explain the embodiments of the present invention or the technical solutions in the prior art, the drawings used in the embodiments are briefly introduced below. Obviously, the drawings in the following description are just some of the present invention For those of ordinary skill in the art, other embodiments may be obtained based on these drawings without paying creative labor.

FIG. 1 is a schematic diagram of the overall structure of the present invention;

FIG. 2 is a left side view of the third positioning space 36, the third gear space 27, and the first positioning space 40 of FIG. 1 according to the present invention;

FIG. 3 is a sectional view of A-A in FIG. 1 of the present invention;

FIG. 4 is a sectional view of B-B in FIG. 1 of the present invention;

FIG. 5 is a sectional view of C-C in FIG. 1 of the present invention..

### DETAILED DESCRIPTION OF THE INVENTION

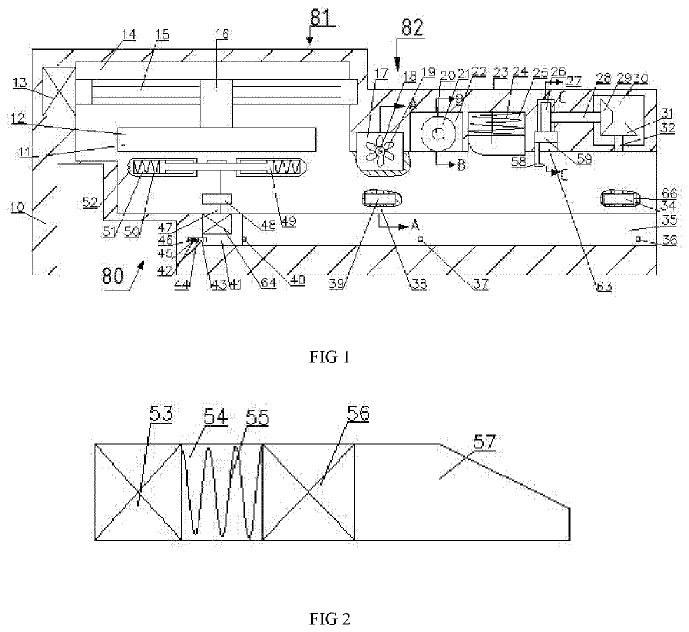

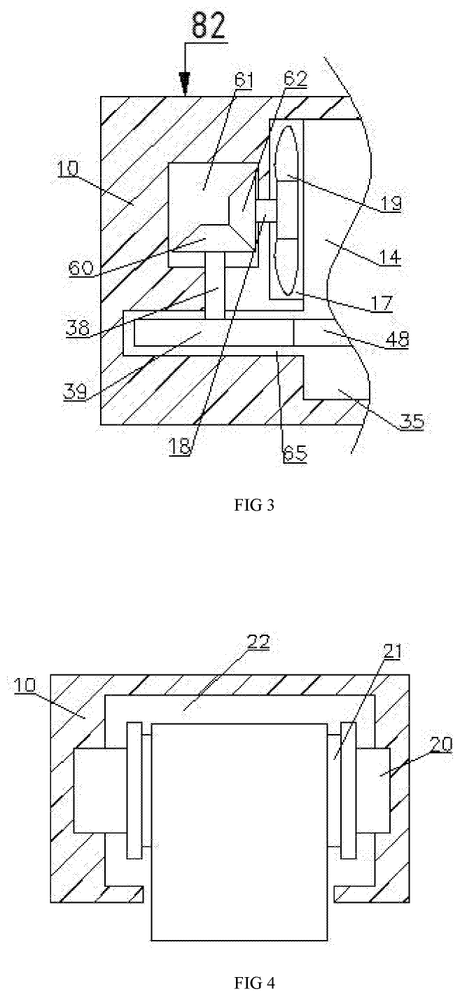

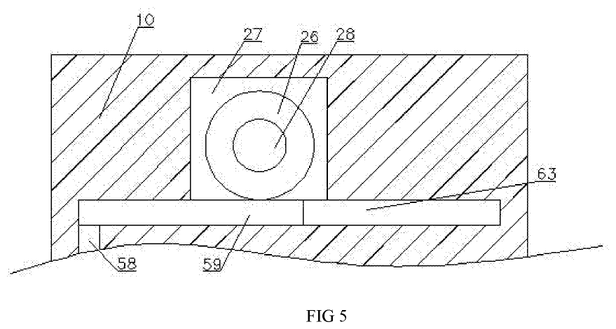

The present invention will be described in detail below with reference to FIGS. 1-5. Among them, for convenience of description, the orientation described below is specified as follows: the up-down, left-right, front-back, and up-down directions described below are consistent with the front, back, left, right, and up and down directions of the view direction of FIG. 1, 1 is a front view of the device of the present invention, and the direction shown in FIG. 1 is the same as the front, rear, left, right, and up and down directions of the device of the present invention.

Referring to FIGS. 1-5, a wire drawing device for a back cover of a metal mobile phone according to an embodiment of the present invention includes a main body 10, and a wire drawing space 14 is provided in the main body 10, and a fixed mobile phone is provided in the wire drawing space 14. A fixing member 80 of the shell. The fixing member 80 includes a support rod 49 rotatably installed in the drawing space 14. Both sides of the support rod 49 are configured to slide and mount fixing blocks 52 symmetrically. A spring space 51. A first spring 50 is fixedly installed between an outer side wall of the first spring space 51 and an outer side surface of the support rod 49. A mobile phone case is sleeved on the support rod 49. The first spring 50 drives the The support rod 49 fixes the mobile phone case on the support rod 49.

The drawing space 14 is provided with a drawing member 81 for drawing the surface of the mobile phone case. The drawing member 81 includes a thread block 16 slidingly installed on the support rod 49 in the drawing space 14. The frosted block base 12 is fixedly installed on the lower side of the block 16, and the frosted block 11 is fixedly installed on the lower side of the frosted block base 12. The frosted block 11 can be contacted with the mobile phone case for drawing.

A fan blade space 17 communicating with the brushed space 14 is located in the rear wall of the brushed space 14 on the right side of the frosted block 11. The fan blade space 17 is provided on the mobile phone case for cleaning the brushed space. A cleaning part 82 of the remaining metal shavings. The cleaning part 82 includes a fan blade 19 which is installed in the fan blade space 17, and when the drawn mobile phone case moves to the front side of the fan blade 19, The fan blade 19 is rotated to blow away the metal chips remaining on the mobile phone case.

In addition, in one embodiment, the fixing member 80 further includes a sliding space 35 provided on the lower side of the drawing space 14 and communicating with the drawing space 14. A motor base 41 is slidably installed in the sliding space 35. A first motor 64 is fixedly installed in the motor base 41, and a fixed shaft 47 is fixedly mounted on the output shaft of the first motor 64. The fixed shaft 47 is fixedly connected to the support rod 49, and the left wall of the sliding space 35 is provided inside. A second spring space 42 is provided. A first energizing magnet 46 is fixedly installed in the left wall of the second spring space 42. A slide bar 43 is slidably installed in the second spring space 42. The slide bar 43 is fixedly installed in the left side surface. The first permanent magnet 44 is fixedly mounted with a second spring 45 between a left side surface of the first permanent magnet 44 and a right side surface of the first energizing magnet 46. When drawing is performed, the first energizing magnet 46 is not energized. The second spring 45 drives the first permanent magnet 44 and the sliding rod 43 to slide to the right to lock and locate the motor base 41 and fix the position of the mobile phone case.

In addition, in an embodiment, a third spring space 54 is provided in the first positioning space 40, a second positioning space 37, and a third positioning space 36, and a second spring is fixedly installed in the rear wall of the third spring space 54. A current-carrying magnet 53, a fixed rod 57 is slidably installed in the second current-carrying magnet 53, a second permanent magnet 56 is fixedly installed in the rear side surface of the fixed rod 57, and a rear side of the second permanent magnet 56 and the second current-carrying magnet A third spring 55 is fixedly installed between the front sides of the 53, and the second energizing magnet 53 is not energized. The third spring 55 drives the second permanent magnet 56 and the fixing rod 57 to move forward, and the motor base 41 is locked and positioned for corresponding processes.

In addition, in an embodiment, the wire drawing component 81 further includes a second motor 13 fixedly installed in the left wall of the wire drawing space 14, and a threaded screw 15 is fixedly installed on the output shaft of the second motor 13. The screw 15 is threadedly connected to the threaded block 16. After the mobile phone shell is tightly fixed to the fixed block 52, the second motor 13 is started. The second motor 13 drives the threaded screw 15 to rotate, and the threaded screw 15 drives the threaded block 16 and matte. The block base 12 and the frosted block 11 are moved to the left and right to wire the mobile phone case. The first motor 64 can also be started. The first motor 64 drives the fixed shaft 47, the support rod 49, and the fixed block 52 to rotate to perform circular wire drawing.

In addition, in one embodiment, the cleaning component 82 further includes a first gear space 65 provided on a lower side of the fan space 17 and communicating with the drawing space 14, and an upper side of the first gear space 65 is located at A first helical gear space 61 is provided on the rear side of the fan blade space 17, and a second rotating shaft 38 is rotatably installed between the top wall of the first gear space 65 and the bottom wall of the first helical gear space 61. A second gear 39 is fixedly installed in the first gear space 65 on the lower side of the two rotating shafts 38, and a first helical gear 60 is fixedly installed in the first helical gear space 61 on the upper side. A fan blade shaft 18 is rotatably mounted between the front wall of the first helical gear space 61 and the rear wall of the fan blade space 17, and a second helical gear is fixedly installed in the first helical gear space 61 in the first helical gear space 61. 62. The second helical gear 62 meshes with the first helical gear 60, the fan blade shaft 18 is fixedly connected to the fan blade 19, and a first gear 48 is fixedly installed on the fixed shaft 47. A gear 48 can be meshed with the second gear 39. After the mobile phone casing is drawn, the motor base 41 is manually moved. To the left of the second positioning space 37, the positioning is locked. The first gear 48 meshes with the second gear 39 to start the first motor 64. The first motor 64 drives the fixed shaft 47, the first gear 48, the second gear 39, and the second gear. The rotating shaft 38, the first helical gear 60, the second helical gear 62, and the fan blade shaft 18 rotate. The fan blade shaft 18 drives the fan blade 19 to rotate, and the rotation of the fan blade 19 generates wind to blow away metal chips on the mobile phone case.

In addition, in one embodiment, a thin film space 22 with a downward opening is located in the top wall of the drawing space 14 on the right side of the fan space 17, and a support shaft 20 is rotatably installed in the thin film space 22. A film shaft 21 is fixedly mounted on the shaft 20, and a plastic film is wound around the film shaft 21. A fourth spring space 25 is provided in the top wall of the drawing space 14 on the right side of the film space 22, and the fourth spring space 25, a pressure block 23 is slidingly installed inside, and a fourth spring 24 is fixedly installed between the upper side of the pressure block 23 and the top wall of the fourth spring space 25. The top wall of the drawing space 14 is located in the fourth spring space 25 of So Sohu. A third gear space 27 is provided on the right side, and a second helical gear space 30 is provided on the right side of the third gear space 27 inside the top wall of the drawing space 14, and a second helical gear space 30 is located inside the rear wall of the drawing space 14. A second gear space 66 is provided on the lower side of the helical gear space 30, and a third rotation shaft 32 is rotatably installed between the top wall of the second gear space 66 and the bottom wall of the second helical gear space 30. The lower side of 32 is fixedly installed in the third gear space 66 in the second gear space 66 The third gear 34 can be meshed with the first gear 48, and a third helical gear 31 is fixedly installed in the second helical gear space 30 on the third rotating shaft 32, and the third gear space 27 is right A fourth rotation shaft 28 is rotatably installed between the wall and the left wall of the second helical gear space 30, and a fourth helical gear 29 is fixedly installed in the second helical gear space 30 on the right side. The fourth helical gear 29 meshes with the third helical gear 31. The left side of the fourth rotation shaft 28 is fixedly installed in the third gear space 27. The fourth gear 26 is fixed in the water area. A rack space 63 is communicated between the drawing spaces 14. A rack 59 is slidably installed in the rack space 63. The rack 59 meshes with the fourth gear 26. The lower side of the rack 59 is fixedly installed. When the knife lever 58 and the motor base 41 are moved to the right to the lower side of the film space 22, the plastic film covers the mobile phone case from right to left, and the pressing block 23 is pressed down, and the pressing block 23 tightly covers the plastic film on the mobile phone case. The motor base 41 moves to the left of the third positioning space 36 to be locked and positioned, and the first gear 48 and the first gear 48 The gear 34 meshes, and the first gear 48 rotates to drive the third gear 34, the third rotation shaft 32, the third helical gear 31, the fourth helical gear 29, the fourth rotation shaft 28, and the fourth gear 26, and the fourth gear 26 drives The rack 59 and the cutter bar 58 move back and forth. The cutter bar 58 moves back and forth to cut the plastic film and complete the drawing.

Initially: the first energized magnet 46 and the second energized magnet 53 are not energized, and the cutter bar 58 is located on the rear wall of the rack space 63;

When in use: when drawing, do not energize the first energized magnet 46, the second spring 45 drives the first permanent magnet 44, slide bar 43 to the right to lock and locate the motor base 41, fix the position of the mobile phone case The second energizing magnet 53 is not energized, and the third spring 55 drives the second permanent magnet 56 and the fixing rod 57 to move forward, and the motor base 41 is locked and positioned for the corresponding process.

After the mobile phone case is tightly fixed on the fixing block 52, the second motor 13 is started. The second motor 13 drives the threaded screw 15 to rotate. The threaded screw 15 drives the threaded block 16, the frosted block base 12, and the frosted block 11 to move left and right to the mobile phone. The shell can be wire-drawn, and the first motor 64 can also be started. The first motor 64 drives the fixed shaft 47, the support rod 49, and the fixed block 52 to rotate to perform circular wire drawing.

After drawing the phone case, the motor base 41 is manually moved to the left of the second positioning space 37 and locked in position. The first gear 48 meshes with the second gear 39 to start the first motor 64. The first motor 64 drives the fixed shaft 47, The first gear 48, the second gear 39, the second rotating shaft 38, the first helical gear 60, the second helical gear 62, and the fan shaft 18 rotate. The fan shaft 18 drives the fan 19 to rotate, and the fan 19 rotates to generate wind. The metal chips on the phone case are blown away. The plastic film covers the phone case from right to left. The pressure block 23 presses down. The pressure block 23 tightly covers the plastic film on the phone case. The motor base 41 moves to the third position. The left side of the space 36 is locked and positioned, the first gear 48 meshes with the third gear 34, and the first gear 48 rotates to drive the third gear 34, the third rotating shaft 32, the third helical gear 31, the fourth helical gear 29, and the fourth The rotating shaft 28 and the fourth gear 26 rotate. The fourth gear 26 drives the rack 59 and the cutter bar 58 to move forward and backward. The cutter bar 58 moves forward and backward to cut the plastic film and complete the drawing.

The beneficial effects of the present invention are: the present invention uses a threaded screw to control the left and right movement of the frosted stone, and the frosted stone contacts the mobile phone case to move left and right to perform drawing. It can better control the cleaning time and the cutting time of the plastic film. The call spring controls the pressure block to slide up and down flexibly, which can make the plastic film fit without damaging the surface of the drawn mobile phone case, which is worth promoting.

Those skilled in the art can clearly understand that various modifications to the above embodiments can be made without departing from the overall spirit and concept of the present invention. They all fall within the protection scope of the present invention. The protection scheme of the present invention is subject to the claims attached to the present invention.

1. A wire drawing device for a rear case of a metal mobile phone, comprising a fuselage, characterized in that: a wire drawing space is provided in the fuselage, and a fixing member for fixing the mobile phone case is provided in the wire drawing space, and the fixing member includes a rotation A support rod installed in the drawing space, and all of the support rods on both sides of the support rod are slidably mounted with fixing blocks; a first spring space is provided in the fixed block; an outer side wall of the first spring space is outside the support rod; A first spring is fixedly installed between the sides, and the mobile phone case is sleeved on the support rod. The first spring drives the support rod to fix the mobile phone case on the support rod. The drawing space is provided for A wire drawing component for drawing the surface of a mobile phone case, the wire drawing component includes a thread block slidingly installed on the upper side of the support rod in the drawing space, and a matte block base is fixedly installed on the lower side of the thread block, and the matte block base A frosted block is fixedly installed on the lower side, and the frosted block can be contacted with the mobile phone case for drawing. A rear wall of the drawing space is located on the right side of the frosted block and is connected with the drawing space. Leaf space, the fan space is provided with a cleaning component for cleaning the metal scraps remaining on the mobile phone case after drawing, the cleaning component includes a fan blade rotatingly installed in the fan space, and the drawing When the subsequent mobile phone case moves to the front side of the fan blade, the fan blade is rotated to blow away the metal shavings remaining on the mobile phone case.
The wire drawing device for a back cover of a metal mobile phone according to claim 1, wherein the fixing member further comprises a sliding space provided on a lower side of the wire drawing space and communicating with the wire drawing space, and A motor base is slidingly installed in the sliding space, a first motor is fixedly installed in the motor base, a fixed shaft is fixedly installed on the output shaft of the first motor, the fixed shaft is fixedly connected to the support rod, and the left wall of the sliding space is A second spring space is provided therein. A first energizing magnet is fixedly installed in the left wall of the second spring space. A slide bar is slidably installed in the second spring space. A first permanent magnet is fixedly installed in the left side of the slide bar. A second spring is fixedly installed between the left side surface of the first permanent magnet and the right side surface of the first energized magnet.
The wire drawing device for a metal mobile phone back case according to claim 1, wherein a third spring space is provided in the first positioning space, the second positioning space, and the third positioning space, and the first A second energized magnet is fixedly installed in the rear wall of the three spring spaces, and a fixed rod is slidably installed in the second energized magnet. A second permanent magnet is fixedly installed in the rear side of the fixed rod. A third spring is fixedly installed between the front side surfaces of the second energizing magnet.
The wire drawing device for a metal mobile phone rear case according to claim 1, wherein the wire drawing part further comprises a second motor fixedly installed in the left wall of the wire drawing space, and the second motor output A threaded screw is fixedly installed on the shaft, and the threaded screw is screwed with the thread block.
The wire drawing device for a metal mobile phone rear case according to claim 1, wherein the cleaning component further comprises a first gear space provided on a lower side of the fan space and communicating with the wire drawing space. A first helical gear space is provided on the upper side of the first gear space and located on the rear side of the fan blade space. A second rotation is installed between the top wall of the first gear space and the bottom wall of the first helical gear space. A second gear is fixedly installed in the first gear space on the lower side of the second rotating shaft, and a first helical gear is fixedly installed in the first helical gear space on the upper side of the second rotating shaft; A fan shaft is rotatably installed between a front wall of the first helical gear space and a rear wall of the fan blade space, and a second helical gear is fixedly installed in the first helical gear space on the fan shaft. A gear meshes with the first helical gear, the fan blade shaft is fixedly connected to the fan blade, a first gear is fixedly mounted on the fixed shaft, and the first gear can mesh with the second gear.
The wire drawing device for a back cover of a metal mobile phone according to claim 1, wherein a thin film space with an opening downward is provided on the right side of the fan space in the top wall of the wire drawing space, and the film A support shaft is rotatably installed in the space, a film shaft is fixedly mounted on the support shaft, a plastic film is wound around the film shaft, and a fourth spring space is located in the top wall of the drawing space on the right side of the film space. A pressure block is slidingly installed in the fourth spring space, and a fourth spring is fixedly installed between the upper side of the pressure block and the top wall of the fourth spring space. The top wall of the drawing space is located on the right side of the fourth spring space of Sosohu. There is a third gear space, a second helical gear space is located on the right side of the third gear space in the top wall of the drawing space, and a first helical gear space is located on the lower side of the second helical gear space in the rear wall of the drawing space. A second gear space, a third rotation shaft is rotatably installed between a top wall of the second gear space and a bottom wall of the second helical gear space, and a lower side of the third rotation shaft is fixedly installed in the second gear space. Three gears A third gear can be meshed with the first gear, a third helical gear is fixedly installed in the second helical gear space on the third rotating shaft, and a right wall of the third gear space and the second helical gear A fourth rotation shaft is rotatably installed between the left walls of the space, and a fourth helical gear is fixedly installed in the second helical gear space on the right side of the fourth rotation shaft, and the fourth helical gear meshes with the third helical gear A fourth gear is fixedly installed in the third gear space on the left side of the fourth rotation shaft, and a rack space is connected between the drawing space in the water space of the third gear space, and the rack space slides in the rack space. A rack is installed, the rack is meshed with the fourth gear, and a cutter bar is fixedly installed on the lower side of the rack.
